(19) United States
(12) Patent Application Publication
(10) Pub. No.: US 2006/0077073 A1
(43) Pub. Date: Apr. 13, 2006

(54) INPUT UNIT HAVING THREE-DIMENSIONALLY ARRANGED KEYS FOR ELECTRONIC DEVICE

(75) Inventor: Li-Chien CHEN, Macau (MO)

Correspondence Address: THE LAW OFFICES OF MIKIO ISHIMARU, 333 W. EL CAMINO REAL, SUITE 330, SUNNYVALE, CA, 94087, US

(73) Assignee: CULTURE.COM TECHNOLOGY (MACAU) LTD., Macau (MO)

(21) Appl. No.: 11/160,978

(22) Filed: Jul. 18, 2005

(30) Foreign Application Priority Data
Oct. 7, 2004 (TW) 093215889

(51) Int. Cl. H03M 11/00; H03K 17/94

(52) U.S. Cl. 341/22

(57) ABSTRACT

An input unit having three-dimensionally arranged keys for an electronic device is proposed. The input unit has at least a plurality of keys, the keys are classified into a plurality of groups and respectively arranged on different planes of the input unit according to the operating functions and properties, so as to extensively arrange the keys on different planes of the input unit, which increases the available area on which the keys can be arranged. The functions of the keys can be identified by users touching on them and locating their relative orientations on the input unit, facilitating the input operations and reducing the probability of mistakenly pressing the wrong keys.

### FIELD OF THE INVENTION

The present invention relates to an input unit for electronic devices, and more specifically, to an input unit for an electronic device that allows users to input operational instructions to an electronic device by pressing keys provided on the input unit.

### BACKGROUND OF THE INVENTION

Conventionally used electronic devices, such as computers, mobile phones, walkmans, remote controllers and so on, provide keys for operation selection function on the top surface thereof or a single lateral face thereof, so that users of the electronic devices can effectively perform input operations.

Referring to FIG. 1, a conventional computer keyboard 100 is shown, wherein the keys arrangement of the computer keyboard 100 is that there are twenty-six English alphabet keys and other operating function keys 101 arranged on its top surface. All of these keys are horizontally arranged on a single surface of the keyboard 100. The space between adjacent keys is totally determined by the available surface area of the keyboard and the amount of the keys to be arranged. That is, the larger the available surface area of the keyboard on which keys can be arranged, and the smaller of the amount of keys to be arranged, the larger of the space between the adjacent keys. If the spaces between the keys are large, users are able to identify key positions on the keyboard more easily, thus the users are provided with a user-friendlier operating environment, and the keys are less likely to be pressed mistakenly. On the contrary, if the spaces between the keys are too small to allow the users to clearly identify the key positions on the keyboard, it is more likely to press the wrong keys, which adds difficulties in operation thereof.

Particularly, to those users having eyes defects or limb movement impediments, an operating keyboard having large spaces between the keys is especially needed; otherwise the small spaces between the keys will make it difficult to operate the keyboard, or even frequently lead to problems like mistakenly pressing the wrong keys.

Referring to FIG. 2, a widely used mobile phone 200 at present is shown. Under the demands for light, thin, short and small semiconductor devices and electronic products, the configuration of the mobile phone is designed to meet the trends of light, thin, short and small, wherein keys 201 of the mobile phone are mainly arranged on a lower portion of a display screen on an upper surface of a main body thereof. Because the configuration of the mobile phones is designed on the demands of light, thin, short and small, the space on its upper surface for arranging the keys is limited, which is even much less after the display screen is disposed. To arrange keys including numerical keys and function keys in such limited space, the space between the keys and the size of the keys have to be reduced, which makes input operation difficult, especially for those users having eyes defects or limb movement impediments.

Further, as to the present mobile phone manufacturers, it is a cruel reality that the products are similarly designed; consequently a breakthrough design idea is a key to winning market competition for the mobile phone manufactures. For example, recently, a kind of mobile phones that can be worn around a user's wrist is found in the market.

However, the position of the input unit of said wristwatch type mobile phone is identical to that of conventional mobile phone, which is arranged on a surface thereof; while under the condition of limited space of the watch surface, the amount and size of keys and space between the keys of the input unit are dramatically restricted. It is not only inconvenient for the operation of normal users, wherein the keys are often mistakenly pressed, but also more inconvenient for those users having eyes defects or limb movement impediments; the design and operation of such mobile phone can not meet the demand for user-friendliness.

### SUMMARY OF THE INVENTION

The primary objective of the present invention is to provide an input unit having three-dimensionally arranged keys for an electronic device, wherein the keys thereof are extensively arranged on each of lateral faces thereof in addition to the upper surface of the main body of the input unit, which increases the available area on which keys can be arranged and the spaces between adjacent keys, therefore facilitating users to locating the keys and reducing the probability of pressing the wrong keys by mistake.

Another objective of the present invention is to provide an input unit having three-dimensionally arranged keys for an electronic device, wherein by increasing area of the main body of the device for arranging keys, the size of the keys can be appropriately increased, providing a user-friendly operating environment for those users having eyes defects.

Still another objective of the present invention is to provide an input unit having three-dimensionally arranged keys for an electronic device, wherein the keys are arranged on an upper surface and each of lateral faces of the input unit, the operating functions of the keys can be recognized by users touching on them and locating their relative orientations on the input unit, therefore providing a user-friendly operating environment for those users having eyes defects.

In accordance with the above and other objectives, the present invention proposes an input unit having three-dimensionally arranged keys for an electronic device, the input unit comprises a plurality of keys, characterized in that the keys are classified into a plurality of groups and respectively arranged on different surfaces of the input unit according to operating functions and properties of the keys. In other words, the keys of the input unit are extensively arranged on at least one of the lateral faces thereof apart from the upper surface. Thus the keys are arranged on different planes of the input unit to increase the area of the input unit for arranging the keys. Consequently, the spaces between adjacent keys can be appropriately increased, and the sizes of the keys can be appropriately increased. The users can easily recognize the operating functions of the keys, and the probability of pressing the wrong keys by mistake can be reduced. Simultaneously, the functions of the keys can be recognized by users touching them and locating their relative orientations on the input unit, thus facilitating the operation and reducing the probability of pressing the wrong keys by mistake.

The present invention is described in the following with specific embodiments, so that one with ordinary skills in the pertinent art can easily understand other advantages and effects of the present invention from the disclosure of the invention. The present invention is also implemented and applied according to other embodiments, and details can be modified based on different views and applications without departing from the spirit of the invention.

### BRIEF DESCRIPTION OF THE DRAWINGS

FIG. 1 is a schematic view showing a conventional computer keyboard;

FIG. 2 is a schematic view showing a conventional mobile phone;

FIG. 3 is a schematic view showing an input unit having three-dimensionally arranged keys for an electronic device applied in a computer keyboard according to an embodiment of the present invention;

FIG. 4 is a schematic view showing an input unit having three-dimensionally arranged keys for an electronic device applied in a mobile phone according to an embodiment of the present invention;

FIG. 5A is a schematic top view showing an input unit having three-dimensionally arranged keys for an electronic device applied in a wristwatch-type mobile phone according to an embodiment of the present invention; and

FIG. 5B is a schematic side view showing the input unit of FIG. 5A.

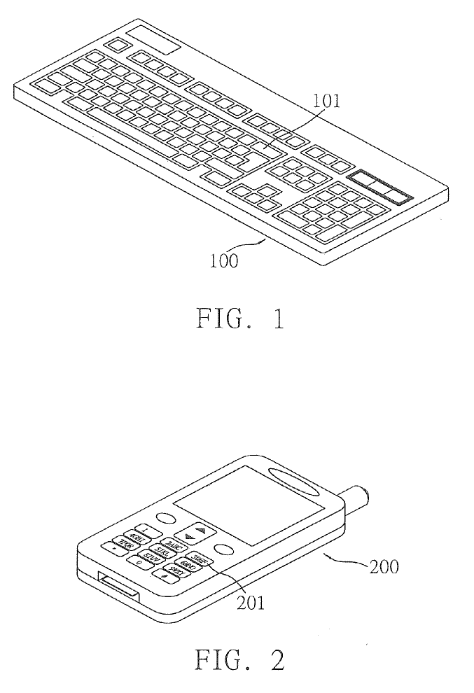

### DETAILED DESCRIPTION OF THE PREFERRED EMBODIMENTS

The following embodiment only serves to provide further description for the present invention with no intent to limit the scope of the invention.

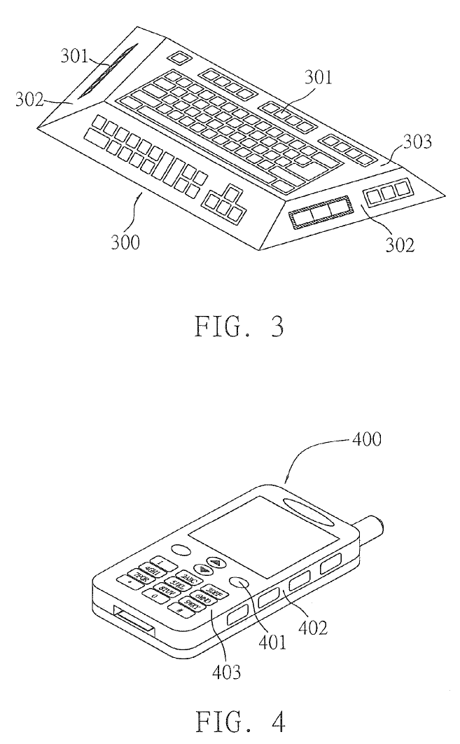

Referring to FIG. 3, a schematic view of an input device having three-dimensionally arranged keys applied in a computer keyboard according to the present invention is shown. As shown in FIG. 3, in order to increase the available surface area of a computer keyboard 300 on which keys 301 can be arranged, a plurality of slanted lateral faces 302 are formed at circumference of the computer keyboard 300, on which a plurality of keys 301 are arranged in addition to an upper surface 303 of the computer keyboard 300. Because the keys 301 formerly arranged only on the upper surface 303 are now additionally arranged on each of the lateral faces 302 of the computer keyboard 300, the area of the computer keyboard 301 for arranging the keys 301 is accordingly increased.

Additionally, the keys 301 can be classified into a plurality of groups according to operation modes and functions thereof, and arranged on each of the lateral faces 302 or the upper surface 303 of the computer keyboard 300 in sequence. For example, the most frequently used twenty-six English alphabet keys may be arranged on the upper surface 303 of the computer keyboard 300; the numerical keys may be arranged on the front slanted lateral face 302 of the computer keyboard 300; other function keys may be arranged on the left and right slanted lateral faces 302 of the computer keyboard 300. As can be seen, the keys 301 can be additionally arranged on each of the lateral faces 302 of the computer keyboard 300, therefore the surface area of the computer keyboard 300 on which keys can be arranged is increased, and in turns the space between adjacent keys can be increased, and the size of the keys can be increased, so that those users having eyes defects or limb movement impediments can more easily identify each key on the keyboard, thus the probability of the keys being mistakenly pressed is thus reduced.

In addition, to those users having serious eyes defects, or even losing their eyesight, the keys 301 of the computer keyboard 300 of the present invention can be classified and arranged on each of the lateral faces 302 and the upper surface 303 of the computer keyboard 300 according to their functions, so that users can promptly recognize the keys 301 based on their relative orientations on the keyboard 300, thus facilitating those users having eyes defects to operate.

Referring to FIG. 4, a schematic view of the input unit having three-dimensionally arranged keys applied in a mobile phone according to the present invention is shown. As shown in FIG. 4, in order to increase the available surface area of a mobile phone 400 on which keys 401 are arranged, lateral faces 402 of the mobile phone are respectively arranged with keys 401. The method of arranging the keys 401 only on the upper surface 403 of the mobile phone 400 in the prior art is extended to arranging keys 401 on the lateral faces 402 of the mobile phone 400. Consequently, the surface area of the mobile phone for arranging the keys 401 is dramatically increased, the spaces between adjacent keys 401 can be appropriately increased, and the size of each of the keys 401 can be appropriately increased. Therefore those users having eyes defects can easily recognize the keys, and the probability of keys being mistakenly pressed is thus reduced.

The keys 401 of the mobile phone 400 can be classified into a plurality of groups according to their functions and properties, and can be arranged on different portions of the mobile phone 400. For example, the most frequently used numerical keys 401 are arranged on the upper surface 403 of the mobile phone 400, and the function keys 401 are respectively arranged on lateral faces 402 of the mobile phone 400. For those users having eyes defects, the operating functions of the keys 401 can be promptly identified based on their relative orientations on the mobile phone 400.

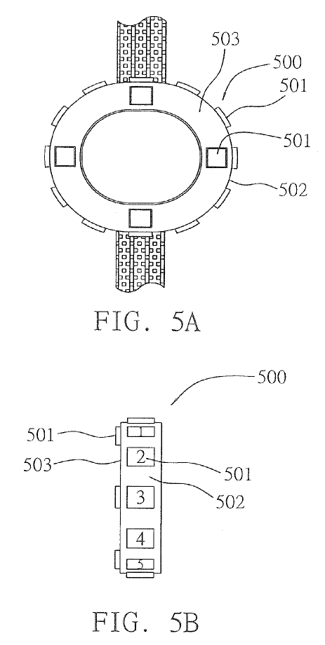

Further referring to FIGS. 5A and 5B, schematic top view and side view of the input unit having three-dimensionally arranged keys in a wristwatch-type mobile phone according to the present invention applied are shown. As shown in FIGS. 5A and 5B, the wristwatch-type mobile phone 500 not only arranges a portion of the keys 501 on a watch surface 503 thereof, but also extensively arranges a plurality of keys 501 on lateral cambered faces 502 thereof. By increasing the area of the wristwatch-type mobile phone 500 for arranging keys 501, the spaces between adjacent keys 501 are increased, and the size of each of the keys 501 can be appropriately increased. Therefore those users having eyes defects can easily recognize the keys, and the probability of pressing the wrong keys is reduced.

In addition, for further facilitating those users having eyes defects to recognize the keys 501 by merely touching them, the keys on the input unit according to the present invention applied in the wristwatch-type mobile phone 500 can be classified into a plurality of groups according to their operating functions and properties and arranged on different portions of the wristwatch-type mobile phone 500. For example, the most frequently used numerical (0˜9) keys 501 are respectively arranged on lateral camber faces in sequence in a clockwise fashion, that is, number 1 is arranged in the one o'clock direction, number 2 is arranged in the two o'clock direction, the rest may be deduced by analogy. Simultaneously, “*” key and “#” key are respectively arranged in the eleven o'clock direction and twelve o'clock direction, and other function keys 501 (such as dialing key and so on) are arranged on the watch surface thereof. Therefore users can recognize the operating functions of the keys 501 by locating them, and the probability of mistakenly pressing the wrong keys is reduced.

In addition, apart from applying the input unit having three-dimensionally arranged keys according to the present invention in the computers and mobile phones as described above, the input unit may also be applied to other electronic devices employing keys, such as electronic watches, walkmans and so on.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. An input unit with three-dimensionally arranged keys for an electronic device, comprising a plurality of keys, characterized in that the keys are classified into a plurality of groups and respectively arranged on different surfaces of the input unit according to operating functions and properties of the keys.

2. The input unit as claimed in claim 1, wherein the operating functions of the keys can be recognized by users touching on them and locating their relative orientations on the input unit.

3. An input unit with three-dimensionally arranged keys for an electronic device, comprising a plurality of keys, the keys being classified into a plurality of groups according to their operating functions and properties and respectively arranged on an upper surface and lateral faces of the input unit.

4. The input unit as claimed in claim 3, wherein the operating functions of the keys can be recognized by users touching on them and locating their relative orientations on the input unit.

5. An input unit having three-dimensionally arranged keys applied in a computer keyboard, comprising an upper surface and a plurality of slanted lateral faces on the circumference thereof and a plurality of keys arranged on the upper surface and each of the lateral faces, wherein the keys are classified into a plurality of groups according to their operating functions and properties and respectively arranged on the upper surface and the lateral faces.

6. The input unit as claimed in claim 5, wherein the keys comprise English alphabet keys arranged on the upper surface of the input unit, numerical keys arranged on a front slanted lateral face of the input unit, and function keys arranged on both sides slanted faces of the input unit.

7. The input unit as claimed in claim 5, wherein the operating functions of the keys can be recognized by users touching on them and locating their relative orientations on the input unit.

8. An electronic device input unit having three-dimensionally arranged keys applied in a mobile phone, comprising an upper surface and a plurality of lateral faces and a plurality of keys arranged on the upper surface and each of the lateral faces, wherein the keys are classified into a plurality of groups according to their operating functions and properties and respectively arranged on the upper surface and the lateral faces.

9. The input unit as claimed in claim 8, wherein the keys comprise numerical keys arranged on the upper surface, and function keys arranged on the lateral faces.

10. The input unit as claimed in claim 8, wherein the operating functions of the keys can be recognized by users touching on them and locating their relative orientations on the input unit.

11. An electronic device input unit having three-dimensionally arranged keys applied in a wristwatch-type mobile phone, comprising an upper surface and a cambered lateral face on the circumference thereof and a plurality of keys arranged on the upper surface and the cambered lateral face, wherein the keys are classified into a plurality of groups according to their operating functions and properties and respectively arranged on the upper surface and the cambered lateral face.

12. The input unit as claimed in claim 11, wherein the keys comprise numerical keys arranged on the lateral cambered face in a clockwise sequence, and function keys arranged on the upper surface.

13. The input unit as claimed in claim 11, wherein the operating functions of the keys can be recognized by users touching on them and locating their relative orientations on the input unit.
